(19) United States
(12) Patent Application Publication
(10) Pub. No.: US 2005/0189648 A1
(43) Pub. Date: Sep. 1, 2005

(54) Semiconductor device

(75) Inventors: Hideki Shirokoshi, Nagaokakyo-shi (JP); Hiroshi Fujinaka, Suita-shi (JP)

Correspondence Address: STEPTOE & JOHNSON LLP, 1330 CONNECTICUT AVENUE, N.W., WASHINGTON, DC, 20036, US

(73) Assignee: Matsushita Elec. Ind. Co. Ltd., Kadoma-shi (JP)

(21) Appl. No.: 11/042,319

(22) Filed: Jan. 26, 2005

(30) Foreign Application Priority Data
Jan. 30, 2004 (JP) 2004-022332

(51) Int. Cl. H01L 23/34

(52) U.S. Cl. 257/724

(57) ABSTRACT

When overvoltage absorption device (3) is disposed so as to surround the periphery of a bonding pad (1) and electrostatically induced overvoltage is applied to a bonding pad section (1A), an overvoltage absorption device (3) is made electrically conductive and absorbs the overvotlage over the entire wiring path connecting the bonding pad (1) and a to-be protected circuit (2). With such configuration, the to-be protected circuit can be protected from electrostatic breakdown, regardless of the wiring direction from the bonding pad section to the to-be protected circuit, and each bonding pad section can be formed as a cell when mask designing is conducted.

### FIELD OF THE INVENTION

The present invention relates to a semiconductor device having a protective circuit for electrostatic breakdown prevention.

### BACKGROUND ART

In order to protect semiconductor integrated circuits from electrostatic breakdown, protective elements or circuits for electrostatic breakdown prevention are introduced and integrated with the terminals.

FIG. 9 shows a conventional semiconductor device, wherein a protective bipolar transistor 3 is provided for the protection of a circuit 2 that is to be protected. Here, the symbol of the protective transistor is also presented in the corresponding location on the cross-sectional view.

An input signal supplied from the outside to the circuit 2 that is formed in the semiconductor substrate 20 and is to be protected is applied to a bonding pad section 1A of an aluminum wiring pattern 71 exposed from a window section 41 of an insulating film 40. The bonding pad section 1A is composed by successively laminating from the bottom upwards a plug 21, an aluminum wiring pattern 72, and a plug 22 between the bonding pad 1 formed on the semiconductor substrate 20 and the lower surface of the aluminum wiring pattern 71.

The input signal applied to the bonding pad section 1A is applied to the circuit 2 that is to be protected via the aluminum wiring pattern 71, a plug 27, and an aluminum wiring pattern 73.

A protective bipolar transistor 3 is formed in the semiconductor substrate 20 located between the bonding pad section 1A and circuit 2 to be protected.

In the protective bipolar transistor 3 formed as a protective circuit, a collector diffusion layer 4 is connected to the aluminum wiring pattern 72 via a plug 23, an emitter diffusion layer 8 is connected to the ground point of the semiconductor substrate 20 via a plug 25, an aluminum wiring pattern 74, and a plug 26, and a base diffusion layer 5 is connected to the aluminum wiring pattern 75 via a plug 24.

In this manner, electrostatic breakdown of the circuit 2 that is to be protected can be prevented because the electrostatic charges applied to the bonding pad 1 escape and are absorbed by the ground of the semiconductor substrate 20 through the protective bipolar transistor 3.

The protective effect demonstrated by the protective bipolar transistor 3 in protecting the circuit 2 from electrostatic breakdown differs depending on the disposition of the protective bipolar transistor 3. In order to obtain a sufficient effect against the electrostatic breakdown of the circuit 2 that is to be protected, the collector diffusion layer 4 of the protective bipolar transistor 3 has to be aligned above the path of the wiring pattern connecting the bonding pad section 1A and circuit 2 that is to be protected.

However, when a plurality of circuits that are to be protected are present on different paths, or in semiconductor devices containing power transistors, an aluminum wiring has to be coated on the bonding pad in order to take care of the cancellation of resistance component of the aluminum wiring or current concentration in the aluminum wiring. However, with the disposition of the protective bipolar transistor 3 as shown in the conventional example, a path is present that connects the bonding pad section 1A and the circuit 2 not via the collector diffusion layer of the protective bipolar transistor 3. Alternatively, it is very difficult to realize a configuration in which the collector diffusion layer 4 of the protective bipolar transistor 3 is disposed above the entire path connecting the bonding pad section 1A and the circuit 2 that is to be protected.

In the conventional example shown in FIG. 10, two circuits 2a, 2b that are to be protected are formed on a semiconductor substrate 20. The reference symbols 21 to 28 denote plugs. Thus, the protective bipolar transistor 3 formed between the bonding pad and one circuit 2a that is to be protected effectively acts to protect the circuit 2a that is to be protected. However, with respect to the other circuit 2b that is connected to the aluminum wiring pattern 71 of the bonding pad section 1A via the plug 28 and aluminum wiring pattern 76, there is a path connecting the bonding pad 1 and the circuit 2b not via the collector diffusion layer 4 of the protective bipolar transistor 3, and a sufficient protection effect against electrostatic breakdown of the circuit 2b cannot be expected.

This result device that a protective bipolar transistor other than the protective bipolar transistor 3 of the circuit 2a that is to be protected is necessary for the circuit 2 to be protected that is connected to the aluminum wiring pattern 71 extending from the bonding pad section 1A in the direction opposite that of the circuit 2a that is to be protected, and when mask design is conducted for each bonding pad section, the designing has to be conducted, while changing the formation position of the protective bipolar transistor according to the wiring direction from the bonding pad sections to the circuits to be protected.

It is an object of the present invention to provide a semiconductor device of a structure making it possible to protect the circuits that are to be protected against electrostatic breakdown, regardless of the wiring direction of the wiring connected from the bonding pad sections to the circuits that are to be protected, and enabling the formation of cells comprising the bonding pad sections and overvoltage absorption device when mask designing is conducted.

### DISCLOSURE OF THE INVENTION

The semiconductor device in accordance with the present invention comprises a semiconductor substrate, a bonding pad section formed on the semiconductor substrate, an overvoltage absorption device formed on the surface of the semiconductor substrate, connected to the bonding pad section and serving for electrostatic breakdown prevention, and a to-be-protected circuit formed on the surface of the semiconductor substrate and connected to the bonding pad section, wherein the overvoltage absorption device is disposed so as to surround the entire periphery of the bonding pad section.

Further, the semiconductor device in accordance with the present invention comprises a semiconductor substrate, a bonding pad section formed on the semiconductor substrate, an overvoltage absorption device formed on the surface of the semiconductor substrate, connected to the bonding pad section and serving for electrostatic breakdown prevention, and a circuit to be protected that is formed on the surface of the semiconductor substrate and connected to the bonding pad section, wherein the overvoltage absorption device is disposed so as to surround part of the outer periphery of the bonding pad section.

Further, in the semiconductor device in accordance with the present invention, the overvoltage absorption device is composed of a bipolar transistor having a collector of the bipolar transistor connected to the bonding pad, a base connected directly or via a resistance to a ground point, and an emitter connected to the ground point.

Further, in the semiconductor device of the present invention, the overvoltage absorption device is composed of a N-channel MOS transistor having a drain connected to the bonding pad and a gate connected to a source, the source being connected to a ground point.

Further, in the semiconductor device of the present invention, the overvoltage absorption device is composed of a P-channel MOS transistor having a drain connected to the bonding pad and a gate connected to a source, the source being connected to a power source.

Further, in the semiconductor device of the present invention, the overvoltage absorption device is composed of a diode having an anode connected to the bonding pad and a cathode connected to a power source.

Further, in the semiconductor device of the present invention, the overvoltage absorption device is composed of a diode having a cathode connected to the bonding pad and an anode connected to a ground point.

With such configuration, the overvoltage absorption device is introduced in a plurality of directions on the outer periphery of the bonding pad section. Therefore, when the mask design is conducted, a sufficient protection effect can be obtained with respect to each bonding pad section, regardless of the extended direction of the wiring from the bonding pad section to the circuit that is to be protected, even when cells are formed by including the bonding pad sections and overvoltage absorption devices and the same type cells are disposed in a plurality of locations.

### BRIEF DESCRIPTION OF THE DRAWINGS

FIG. 1 is a cross-sectional view of a semiconductor device of Embodiment 1 of the present invention;

FIG. 2 is a plan view of the same embodiment;

FIG. 3 is a plan view of a semiconductor device of Embodiment 2 of the present invention;

FIG. 4 is a cross-sectional view of a semiconductor device of Embodiment 3 of the present invention;

FIG. 5 is a plan view of the same embodiment;

FIG. 6 is another plan view of the same embodiment;

FIG. 7 is a cross-sectional view of a semiconductor device of Embodiment 4 of the present invention;

FIG. 8 is a plan view of the same embodiment;

FIG. 9 is a cross-sectional view of a configuration of a conventional semiconductor device;

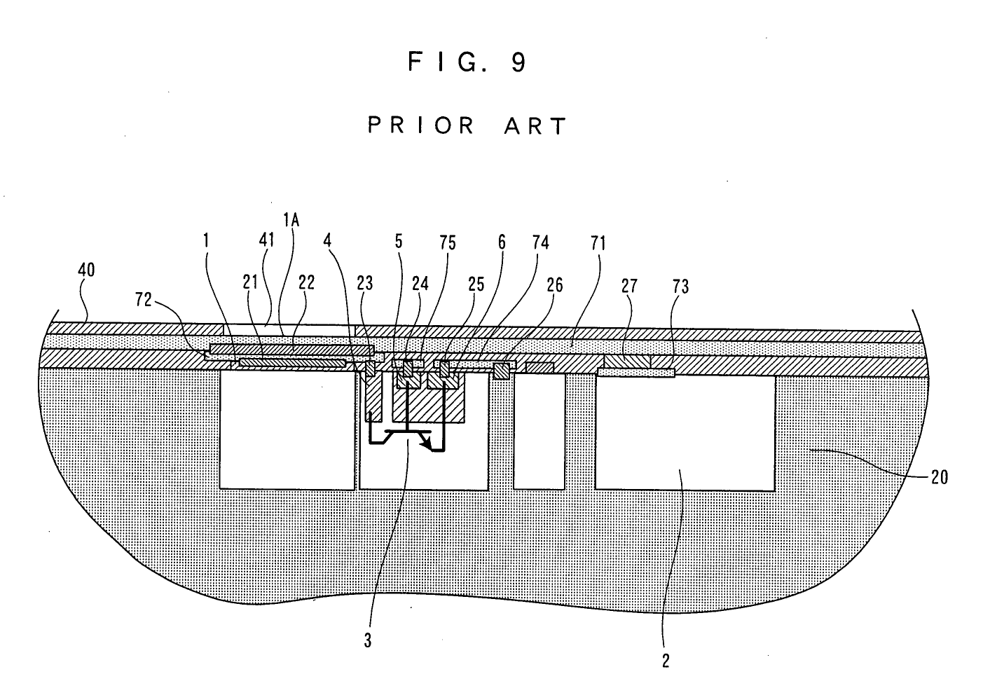

FIG. 10 is a cross-sectional view of a configuration of a conventional semiconductor device;

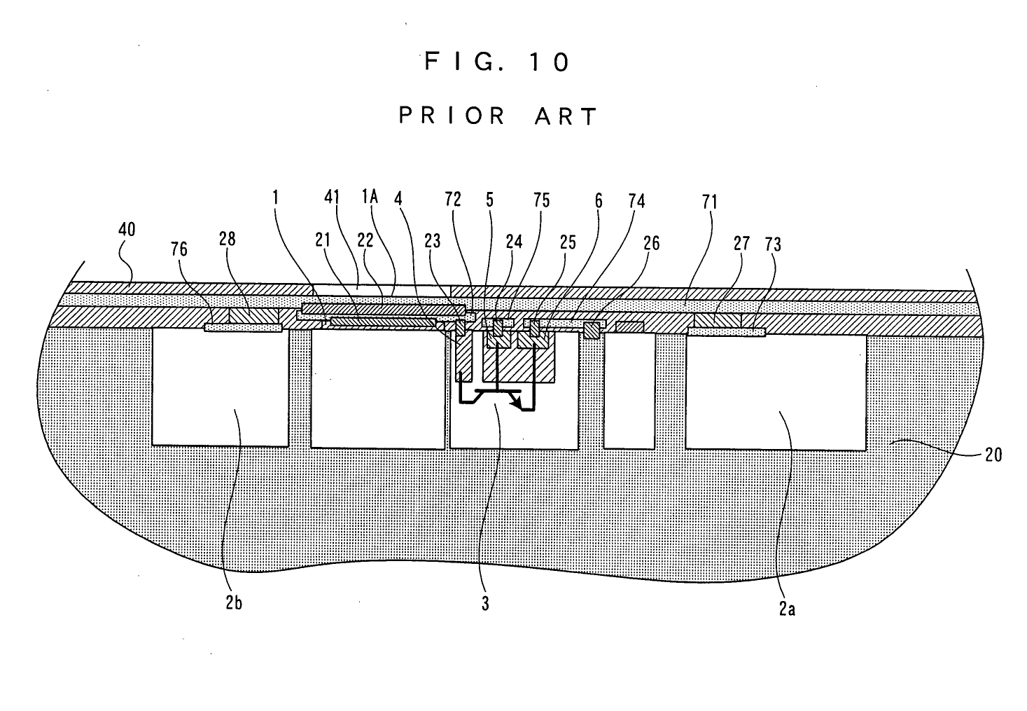

FIGS. 11A to 11D are a plan view illustrating the mask design in Embodiment 1 of the present invention and enlarged views of a bonding pad section;

FIGS. 12A and 12B are cross-sectional views of FIG. 11B and FIG. 11C; and

FIG. 13 is a cross-sectional view of the main part of FIG. 6.

### DESCRIPTION OF EMBODIMENTS

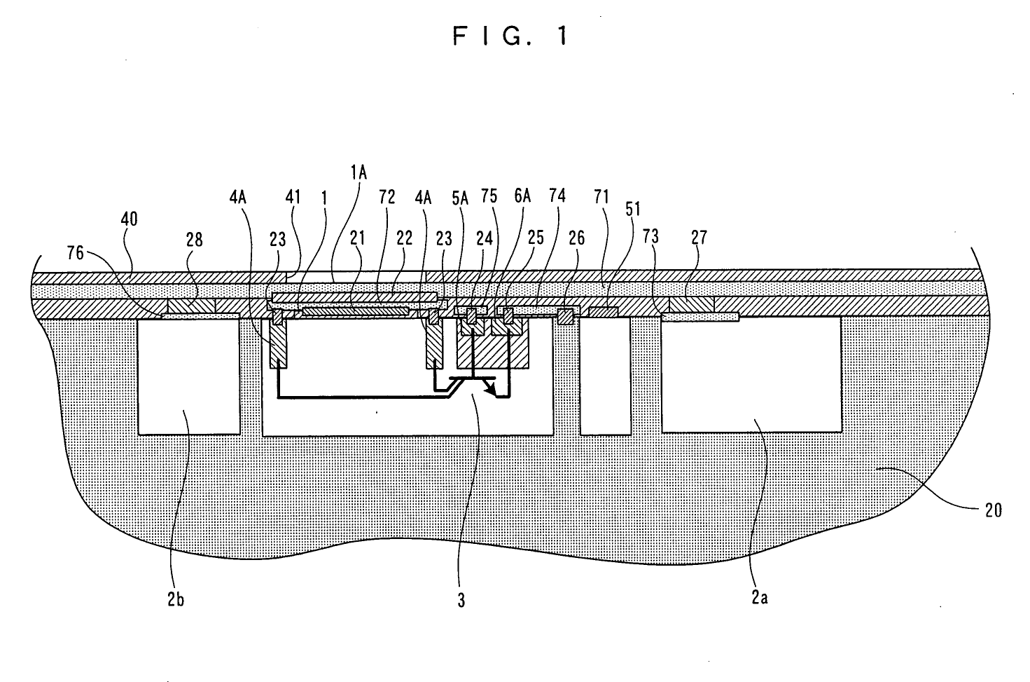

The embodiments of the present invention will be described hereinbelow with reference to FIGS. 1 to 8 and FIGS. 11 to 13.

### Embodiment 1

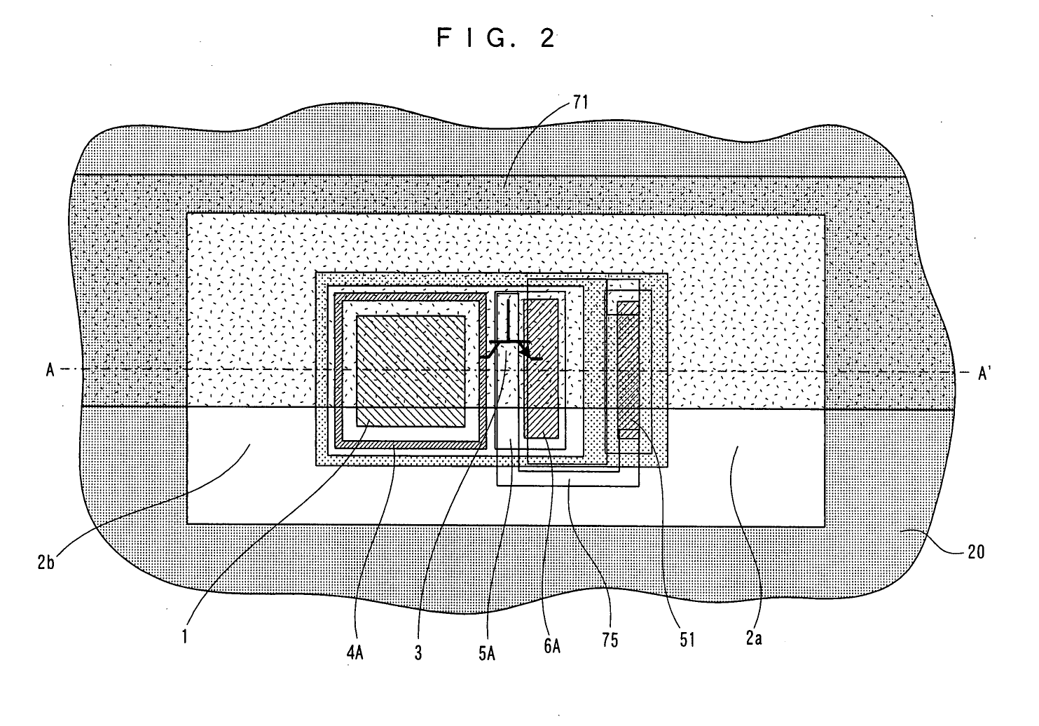

FIG. 1 and FIG. 2 show a semiconductor device of Embodiment 1 of the present invention.

FIG. 1 is a cross-sectional view along the A-A′ line in the plan view of the semiconductor device sown in FIG. 2.

The semiconductor device of Embodiment 1 comprises a protective bipolar transistor 3 for protecting the circuits 2a, 2b that are to be protected. Here, the symbol of the protective transistor is also presented in the corresponding location on the cross-sectional view.

A bonding pad section 1A is composed by successively laminating from the bottom upwards a plug 21, an aluminum wiring pattern 7, and a plug 22 between the bonding pad 1 formed on a semiconductor substrate 20 and the lower surface of an aluminum wiring pattern 71.

With respect to the circuits 2a, 2b that are formed in the semiconductor substrate 20 and are to be protected, an input signal from the outside is applied to the bonding pad section 1A of the aluminum wiring pattern 71 exposed from a window section 41 of an insulating film 40. Further, the input signal applied to the bonding pad section 1A is applied to the circuit 2a, which is to be protected, via the aluminum wiring pattern 71, a plug 27, and an aluminum wiring pattern 73. To the circuit 2b that is to be protected, the input signal is applied via the aluminum wiring pattern 71, a plug 28, and an aluminum wiring pattern 76. The output signal to the outside is transmitted in the opposite direction.

In the protective bipolar transistor 3 serving as overvoltage absorption device, a collector diffusion layer 4A is so formed as to surround the entire periphery of the bonding pad section 1A as shown in FIG. 2. More specifically, the collector diffusion layer 4A formed on the surface of the semiconductor substrate 20 is so formed on the outer periphery of the bonding pad 1 as to surround the bonding pad 1. Therefore, FIG. 1 shows not only the collector diffusion layer 4A connected via the plug 23 to the wiring pattern between the bonding pad section 1A and circuit 2a that is to be protected, but also the collector diffusion layer 4A connected via the plug 23 to the wiring pattern between the bonding pad section 1A and circuit 2b that is to be protected, and those two collector diffusion layers 4A are the same continuous collector diffusion layer that is incorporated in the semiconductor substrate 20.

The emitter diffusion layer 6A of the protective bipolar transistor 3 is connected to the ground point of the semiconductor substrate 20 via a plug 25, an aluminum wiring pattern 74, and a plug 26. A base diffusion layer 5A is connected to the grounding point of the semiconductor substrate 20 via a plug 24, an aluminum wiring pattern 75, and a resistance element 51.

Referring to FIG. 1, the aluminum wiring pattern 71 of the uppermost layer covers the entire surface of the semiconductor substrate 20. In FIG. 2, part of the aluminum wiring pattern 71 of the uppermost layer is removed to show the lower side thereof. Plugs are not shown in the figures either.

FIG. 2 is explained below in greater detail. Because the collector diffusion layer 4A of the protective bipolar transistor 3 is so disposed as to surround the entire periphery of the bonding pad 1 and the entire periphery of the lower surface of the aluminum wiring pattern 72 covering the bonding pad 1 is conductively connected to the collector diffusion layer 4A of the protective bipolar transistor 3, not only the circuit 2a can be protected against electrostatic breakdown, but also the protective bipolar transistor 3 can effectively act upon the circuit 2b that has a different orientation of wiring from the bonding pad section 1A and the circuit 2b can be protected against electrostatic breakdown.

In Embodiment 1, the base diffusion layer 5 of the protective bipolar transistor 3 is grounded via the resistance element 51, but the protection effect against electrostatic breakdown obviously can be obtained when the base diffusion layer 5 of the protective bipolar transistor 3 is grounded and when this circuit is open.

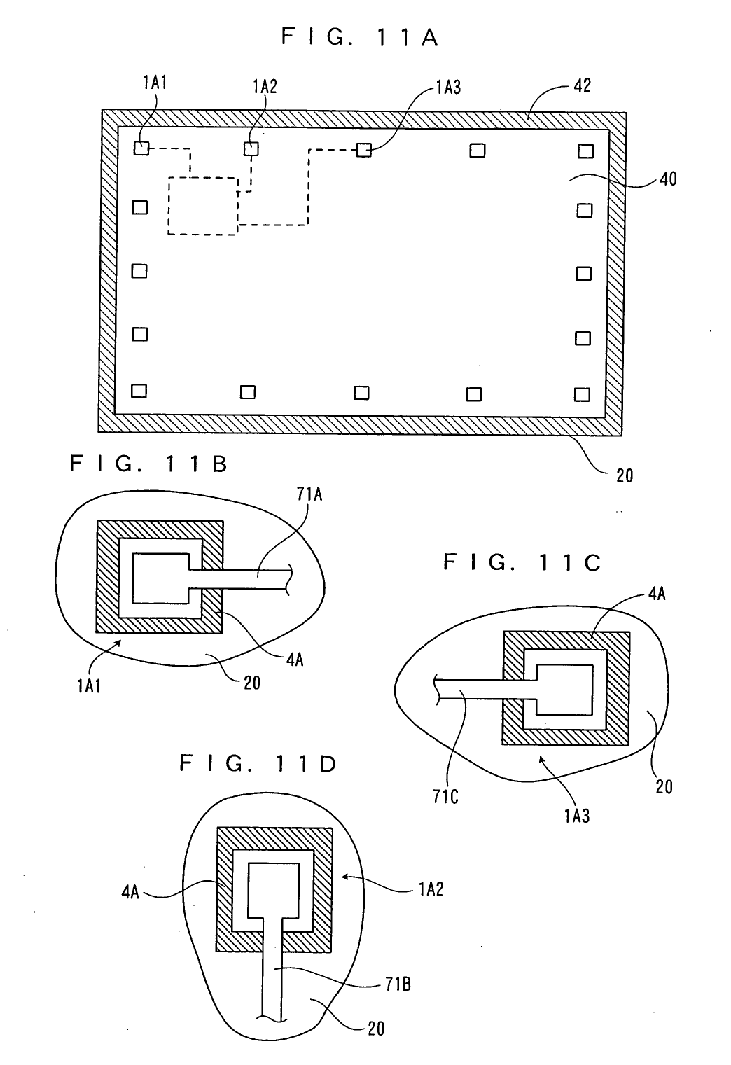

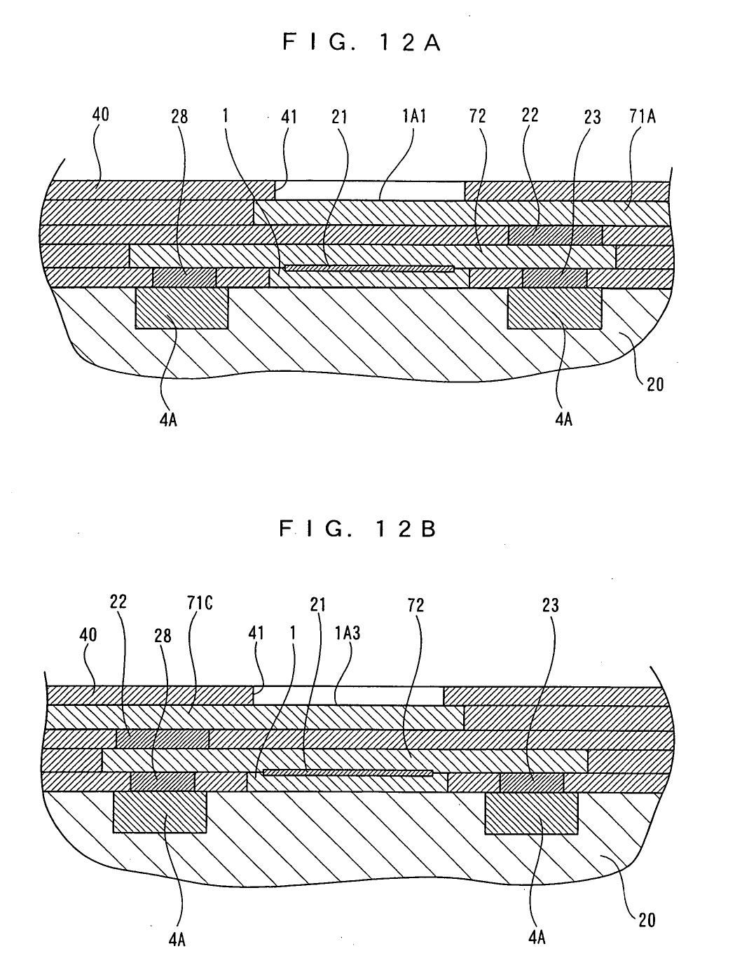

In the above-described Embodiment 1, an example was explained in which the entire surface of the semiconductor substrate 20 was covered with the aluminum wiring pattern 71 of the uppermost layer. The formation of a cell comprising a bonding pad section and an overvoltage absorption device when mask designing is conducted will be explained below with reference to an example based on FIG. 11 and FIG. 12.

FIG. 11(A) is a plan view of a semiconductor device, wherein a ground pattern 42 is formed along the outer periphery of the semiconductor substrate 20. Among the bonding pad sections 1A1, 1A2, 1A3, . . . exposed from the window sections of the insulating film 40, only bonding pad sections 1A1, 1A2, 1A3 will be considered herein.

As for the direction of the wiring pattern connecting the circuit 2 that is formed on the surface of the semiconductor substrate 20 and has to be protected and the bonding pad sections 1A1, 1A2, 1A3, with respect to the bonding pad section 1A1, the aluminum wiring pattern 71A is extended rightward, as shown in FIG. 11(B). With respect to the bonding pad section 1A2, the aluminum wiring pattern 71B is extended downward, as shown in FIG. 11(D). With respect to the bonding pad section 1A3, the aluminum wiring pattern 71C is extended leftward, as shown in FIG. 11(C).

As shown in FIGS. 11(B)-(D), the protective bipolar transistor 3 acting so that it can protect the circuit 2 against the electrostatic breakdown can be incorporated in any of the bonding pad sections 1A1, 1A2, 1A3 by forming the collector diffusion layer 4A of the protective bipolar transistor 3 on the surface of the semiconductor substrate 20 so as to surround the entire periphery of the bonding pad section. Therefore, it is apparent that when mask designing is conducted, each bonding pad section 1A1, 1A2, 1A3 may be composed by forming cells comprising the bonding pad 1 and protective bipolar transistor 3 and disposing a plurality of the cells of the same type.

FIG. 12(A) is a cross-sectional view of the bonding pad section 1A1, FIG. 12(B) is a cross-sectional view of the bonding pad section 1A3. Components identical to those shown in FIG. 1 are denoted by identical reference symbols.

### Embodiment 2

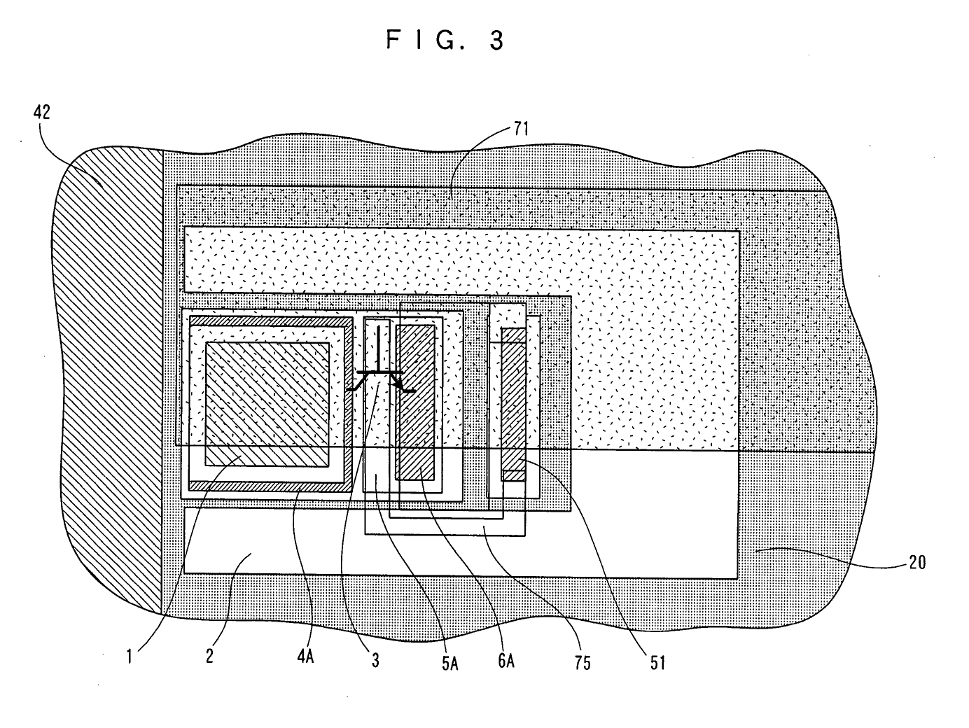

FIG. 3 is a plan view of the semiconductor device of Embodiment 2 of the present invention. The symbol of the protective transistor is also presented in the corresponding location on the cross-sectional view and explained in the same manner as in Embodiment 1.

The cross-sectional structure of the semiconductor device is basically almost identical to that shown in FIG. 1, with part of the collector diffusion layer 4A missing.

In the above-described Embodiment 1, the collector diffusion layer 4A of the protective bipolar transistor 3 was formed in the semiconductor substrate 20 so as to surround the entire periphery of the bonding pad section 1A, but in the configuration shown in FIG. 3, the formation region of the circuit 2 that is to be protected in the semiconductor substrate 20 is formed to have a shape surrounding the bonding pad 1 on three sides.

In this case, the collector diffusion layer 4A is formed to surround part of the outer periphery of the bonding pad section 1A, and the bonding pad 1 and collector diffusion layer 4A are electrically connected by the aluminum wiring pattern (denoted by numeral 72 in FIG. 1) covering the bonding pad 1. The base diffusion layer 5A of the protective bipolar transistor 3 is connected to the ground point (semiconductor substrate 20) directly or via the aluminum wiring pattern 75 and resistance element 51, and the emitter diffusion layer 6A is connected to the ground point.

Further, referring to FIG. 3, the aluminum wiring patterns 42 and 71 of the uppermost layer cover the entire surface of the semiconductor substrate 20, but part thereof is removed to show the lower side of the aluminum wiring pattern 71 of the uppermost layer. Plugs are not shown in the figure either.

In semiconductor devices of general type, as shown in FIG. 11(A), a ground pattern 42 is formed along the outer periphery of the semiconductor substrate 20 and a plurality of bonding pad sections 1A are disposed along this ground pattern 42. For this reason, semiconductor elements are disposed inside the semiconductor substrate 20 and no semiconductor elements are disposed on the chip end side of the semiconductor substrate 20. Therefore, if a bonding pad section 1A having a collector diffusion layer 4A on three sides, as in the present embodiment, is disposed so that one more side where the collector diffusion layer 4A is missing faces the ground pattern 42 side of the chip end, then the collector diffusion layer 4A on the three sides where the semiconductor elements are formed is disposed substantially on the entire path of the wiring pattern and a sufficient protection effect against electrostatic breakdown can be obtained substantially for the entire circuit 2 that is to be protected.

### Embodiment 3

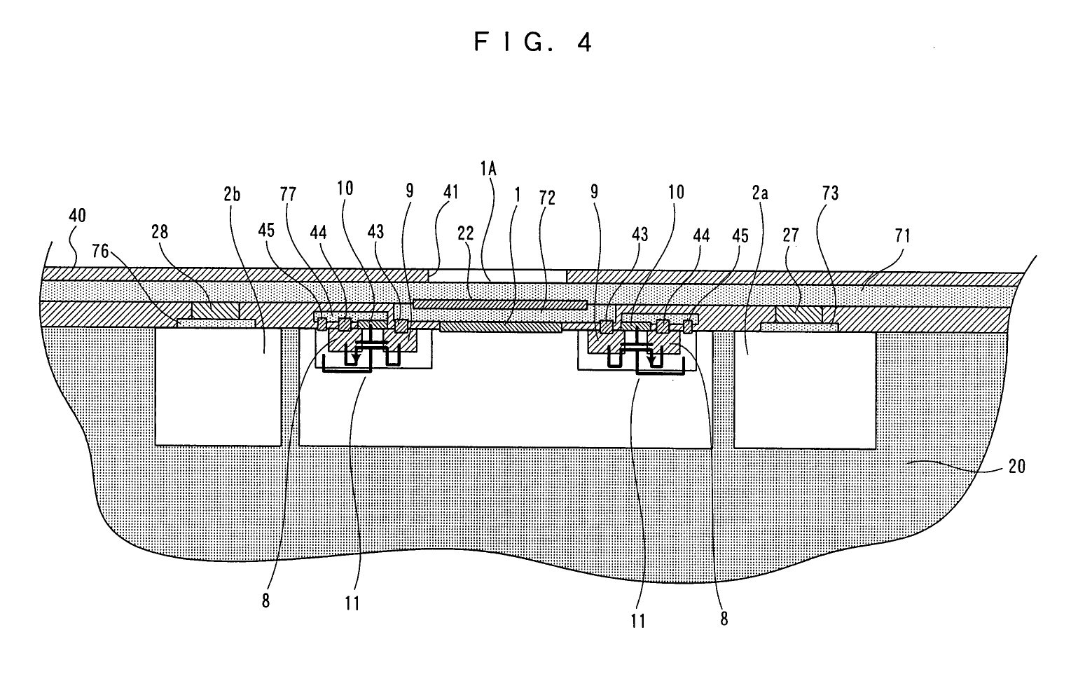

FIGS. 4 to 6 show the semiconductor device of Embodiment 3 of the present invention.

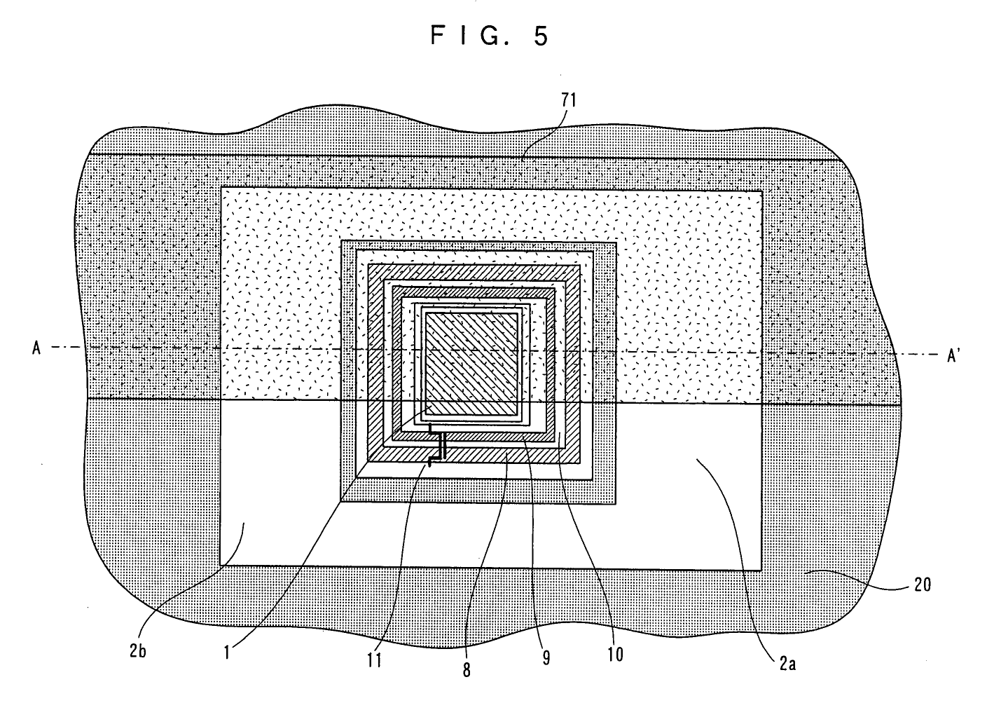

FIG. 4 is a cross-sectional view along the A-A′ line in the plan view of the semiconductor device shown in FIG. 5. The symbol of the protective transistor is also presented in the corresponding location on the cross-sectional view in the same manner as in Embodiment 1.

Referring to FIG. 4 and FIG. 5, the bonding pad section 1A is composed by successively laminating from the bottom upwards the plug 21, aluminum wiring pattern 72, and plug 22 between the bonding pad 1 formed on the semiconductor substrate 20 and the lower surface of the aluminum wiring pattern 71.

With respect to the circuits 2a, 2b that are formed in the semiconductor substrate 20 and are to be protected, an input signal from the outside is applied to the bonding pad section 1A of the aluminum wiring pattern 71 exposed from the window section 41 of the insulating film 40. Further, the input signal applied to the bonding pad section 1A is applied to the circuit 2a that is to be protected via the aluminum wiring pattern 71, plug 27, and aluminum wiring pattern 73. To the circuit 2b that is to be protected, the input signal is applied via the aluminum wiring pattern 71, plug 28, and aluminum wiring pattern 76. The output signal to the outside is transmitted in the opposite direction.

In a protective N channel MOS transistor 11 (referred to hereinbelow as “protective MOS transistor”) 11 serving as overvoltage absorption device, a drain diffusion layer 9 is so formed in the surface of the semiconductor substrate 20 as to surround the entire periphery of bonding pad section 1A, a gate electrode 10 is formed on the outside thereof, and the source diffusion layer 8 is formed in the semiconductor substrate 20 so as to surround the entire periphery on the outside of the gate electrode.

More specifically, the drain diffusion layer 9 and source diffusion layer 8 formed in the semiconductor substrate 20 are so formed on the outer periphery of the bonding pad 1 as to surround the bonding pad 1. The drain diffusion layer 9 is connected on the entire periphery of the outer peripheral section of the aluminum wiring pattern 72 to the aluminum wiring pattern 72 via the plug 43. The source diffusion layer 8 is connected to an aluminum wiring pattern 77 via a plug 44. The reference numeral 45 stands for a plug. The gate electrode 10 is connected to the source diffusion layer 8, and the source diffusion layer 8 is connected to the grounding point (semiconductor substrate 20). A thin gate oxidation film (not shown in the figure) is formed on the semiconductor substrate 20 located directly below the gate electrode 10.

Referring to FIG. 4, the aluminum wiring pattern 71 of the uppermost layer covers the entire surface of the semiconductor substrate 20. In FIG. 5, part of the aluminum wiring pattern 71 of the uppermost layer is removed to show the lower side thereof. Plugs are not shown in the figure either.

Referring to FIG. 5, a configuration in which the drain diffusion layer 9 of the protective MOS transistor 11 is introduced over the entire path connecting the bonding pad 1 and the circuits 2a, 2b that are to be protected can be easily realized by disposing the drain diffusion layer 9 of the protective MOS transistor 11 so as to surround the entire periphery of the bonding pad 1 and conductively connecting the bonding pad 1 and the drain diffusion layer 9 of the protective MOS transistor 11 with the aluminum wiring pattern 72. With such configuration, a sufficient protection effect against electrostatic breakdown is obtained for the entire circuits 2a, 2b.

Further, the gate electrode of the protective MOS transistor 11 is directly grounded, but the effect against electrostatic breakdown obviously can be also obtained when grounding is conducted via a resistance element. Further, in Embodiment 3, the N-channel MOS transistor is used as the protective MOS transistor 11, but it goes without saying that a P-channel MOS transistor can be also used. In this case, a power source will replace the ground.

Further, the same effect can be also obtained by disposing the drain diffusion layer 9 of the protective MOS transistor 11 so as to surround part (more specifically, on three sides) of the outer periphery of the bonding pad 1 and to connect electrically the bonding bad 1 and the drain diffusion layer 9 of the protective MOS transistor 11 with the aluminum wiring pattern 72 covering the bonding pad 1, as in Embodiment 2.

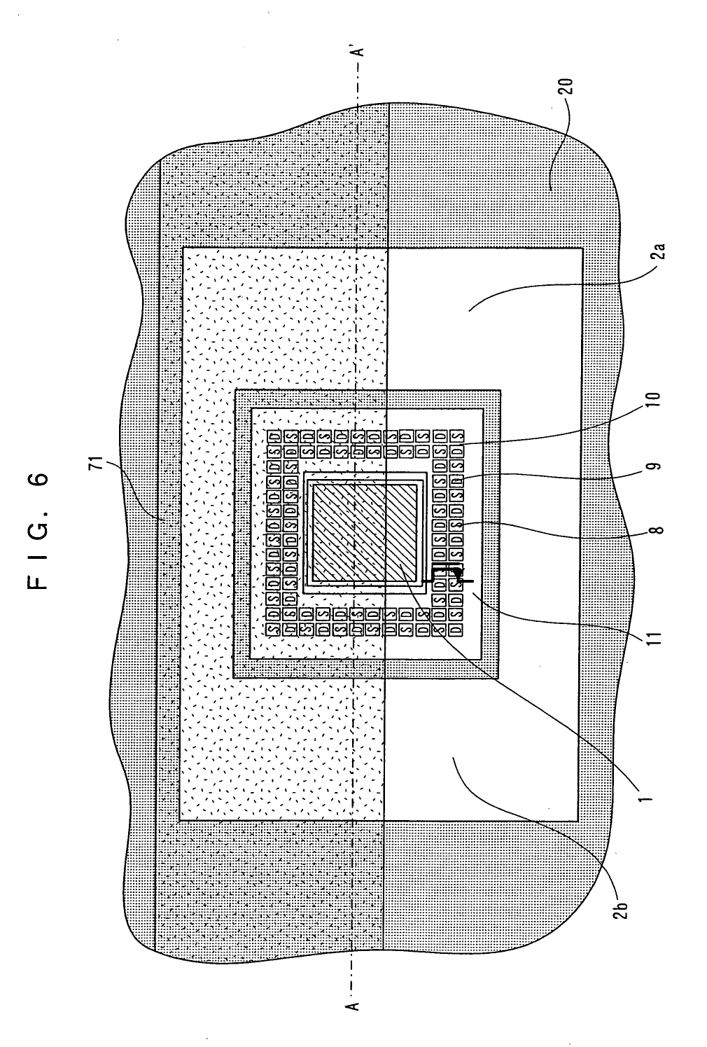

As shown in the plan view in FIG. 6, it is also possible to form cells from the source diffusion layer 8 and the drain diffusion layer 9 of the protective MOS transistor 11 and to dispose the cells in the form of a mesh. In the structures of MOS power devices that came recently into use, the drains and sources are mesh-like disposed as cells. Therefore, in this case, disposing a protective MOS transistor of the output bonding pad for the MOS power device as shown in FIG. 6 makes it possible to improve coupling with the peripheral power devices and to obtain a sufficient protective effect with respect to electrostatic breakdown.

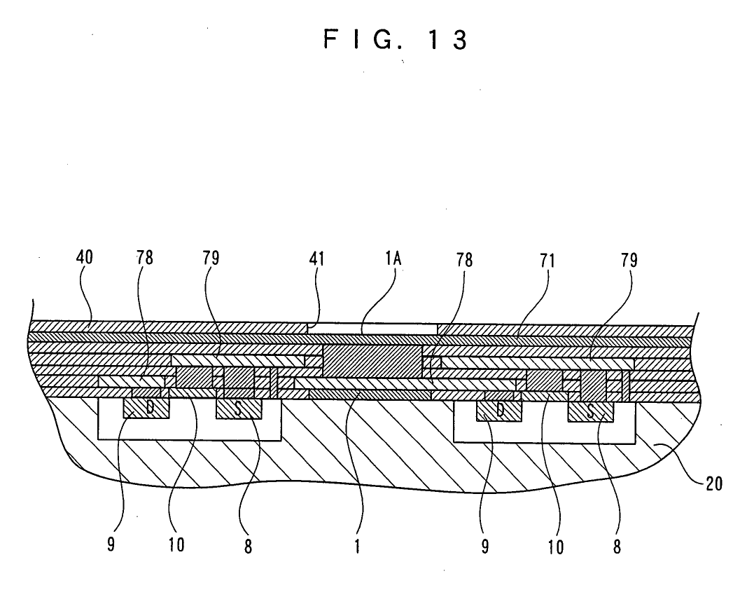

FIG. 13 is a cross-sectional view illustrating the case where the drain diffusion layer 9 and source diffusion layer 8 of the protective MOS transistor 11 are disposed in the form of a mesh as shown in FIG. 6. Here, parts of the mesh-like drain diffusion layer 9 are connected to each other with an aluminum wiring pattern 78. Parts of the mesh-like drain source diffusion layer 8 are connected to each other with the aluminum wiring pattern 79 drawn to the layer above the aluminum wiring pattern 78.

### Embodiment 4

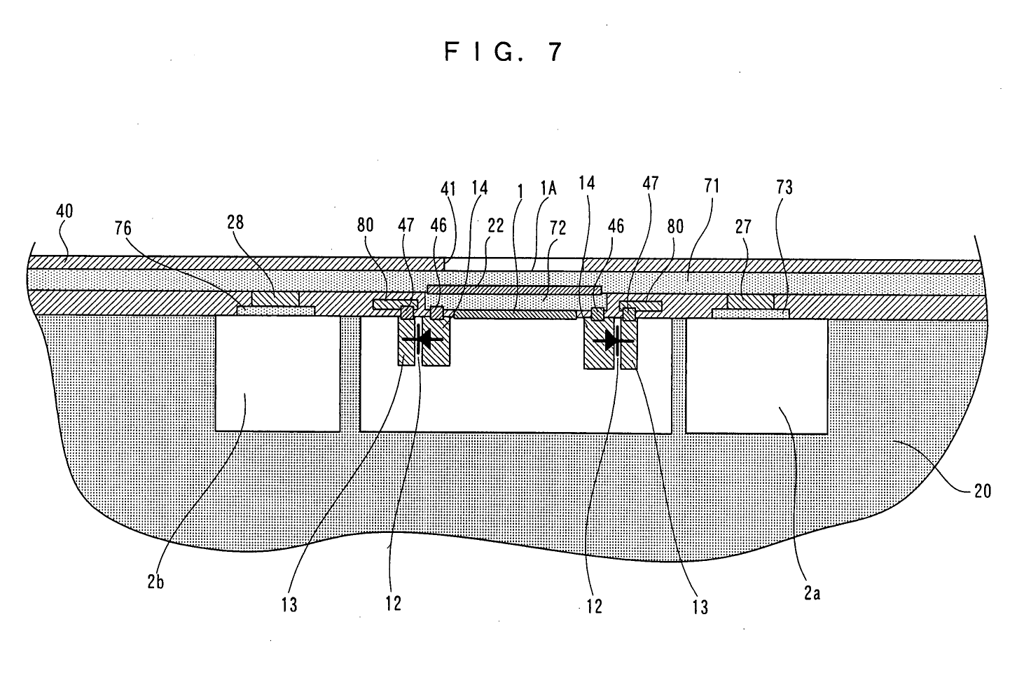

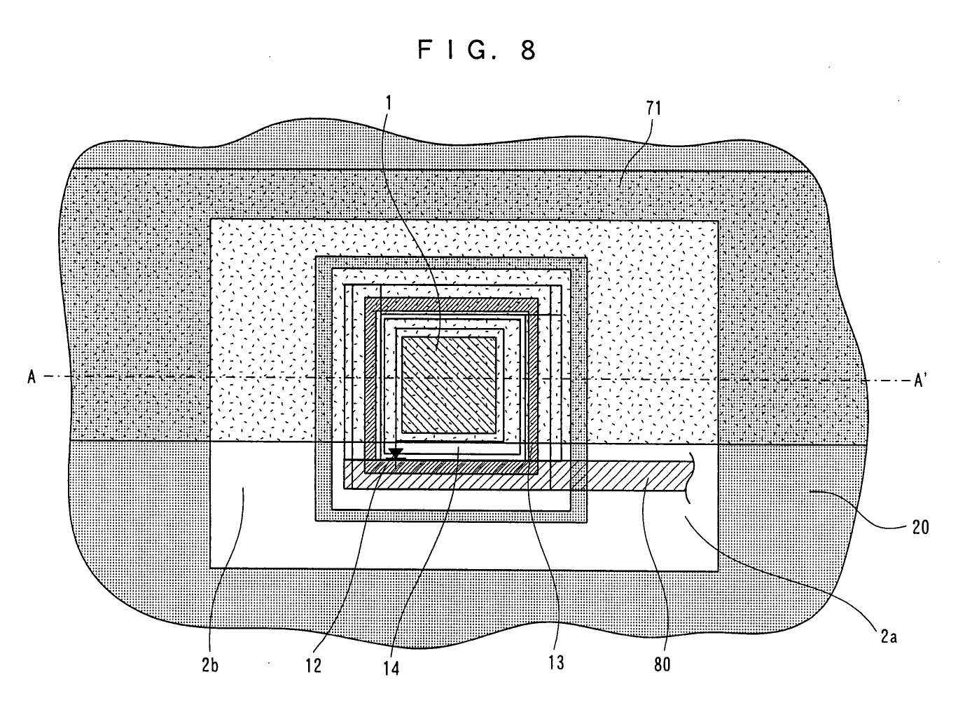

FIGS. 7 and 8 show the semiconductor device of Embodiment 4 of the present invention.

FIG. 7 is a cross-sectional view along the A-A′ line in the plan view of the semiconductor device shown in FIG. 8. The symbol of the protective transistor is also presented in the corresponding location on the cross-sectional view in the same manner as in Embodiment 1.

The bonding pad section 1A is composed by successively laminating from the bottom upwards the plug 21, aluminum wiring pattern 72, and plug 22 between the bonding pad 1 formed on the semiconductor substrate 20 and the lower surface of the aluminum wiring pattern 71.

With respect to the circuits 2a, 2b that are formed in the semiconductor substrate 20 and are to be protected, an input signal from the outside is applied to the bonding pad section 1A of the aluminum wiring pattern 71 exposed from the window section 41 of the insulating film 40. Further, the input signal applied to the bonding pad section 1A is applied to the circuit 2a that is to be protected via the aluminum wiring pattern 71, plug 27, and aluminum wiring pattern 73. To the circuit 2b that is to be protected, the input signal is applied via the aluminum wiring pattern 71, plug 28, and aluminum wiring pattern 76. The output signal to the outside is transmitted in the opposite direction.

Referring to FIG. 8, in a protective diode 12 serving as overvoltage absorption device, an anode diffusion layer 14 is so disposed as to surround the entire periphery of bonding pad 1, and the bonding pad 1 and anode diffusion layer 14 are conductively connected via the plug 46 to the aluminum wiring patter 72 covering the bonding pad 1. The cathode diffusion layer 13 of the protective diode 12 is connected to a power source via the plug 47 and aluminum wiring pattern 80.

In this manner a configuration can be easily realized in which the anode diffusion layer 14 of the protective diode 12 is introduced over the entire part connecting the bonding pad 1 and the circuits 2a, 2b that are to be protected. With such configuration, a sufficient protection effect against electrostatic breakdown is obtained for the entire circuits 2a, 2b.

In Embodiment 4, the anode diffusion layer 14 of the protective diode 12 is used as overvoltage absorption device, but it goes without saying that a cathode diffusion layer 13 of the protective diode 12 can be also used. In this case, the power source will stand for ground.

Referring to FIG. 7, the aluminum wiring pattern 7 of the uppermost layer covers the entire surface of the semiconductor substrate 20. In FIG. 8, part of the aluminum wiring pattern 7 of the uppermost layer is removed to show the lower side thereof. Plugs are not shown in the figures either.

Further, the same effect can be also obtained by disposing the anode diffusion layer 14 of the protective diode 12 so as to surround part of the outer periphery of the bonding pad 1 and to connect electrically the bonding pad 1 and the anode diffusion layer 14 of the protective diode 12 with the aluminum wiring pattern 7 covering the bonding pad 1, as in Embodiment 2.

The present invention can be used to improve reliability of semiconductor devices integrated by introducing a protective circuit for electrostatic breakdown prevention and of various electric devices using such semiconductor devices.

1. A semiconductor device, comprising:
a semiconductor substrate;
a bonding pad section formed on the semiconductor substrate;
an overvoltage absorption device formed on the surface of the semiconductor substrate, connected to the bonding pad section and serving for electrostatic breakdown prevention; and
a to-be-protected circuit formed on the surface of the semiconductor substrate and connected to the bonding pad section, wherein
the overvoltage absorption device is disposed so as to surround the entire periphery of the bonding pad section.

2. A semiconductor device, comprising:
a semiconductor substrate;
a bonding pad section formed on the semiconductor substrate;
an overvoltage absorption device formed on the surface of the semiconductor substrate, connected to the bonding pad section and serving for electrostatic breakdown prevention; and
a to-be-protected circuit formed on the surface of the semiconductor substrate and connected to the bonding pad section, wherein
the overvoltage absorption device is disposed so as to surround part of the outer periphery of the bonding pad section.

3. The semiconductor device according to claim 1, wherein the overvoltage absorption device is composed of a bipolar transistor, the bipolar transistor having a collector connected to the bonding pad, a base connected directly or via a resistance to a ground point and an emitter connected to the ground point.

4. The semiconductor device according to claim 1, wherein the overvoltage absorption device is composed of a N-channel MOS transistor, the N-channel MOS transistor having a drain connected to the bonding pad and a gate connected to a source, the source being connected to a ground point.

5. The semiconductor device according to claim 1, wherein the overvoltage absorption device is composed of a P-channel MOS transistor, the P-channel MOS transistor having a drain connected to the bonding pad and a gate connected to a source, the source being connected to a power source.

6. The semiconductor device according to claim 1, wherein the overvoltage absorption device is composed of a diode, the diode having an anode connected to the bonding pad and a cathode connected to a power source.

7. The semiconductor device according to claim 1, wherein the overvoltage absorption device is composed of a diode, the diode having a cathode connected to the bonding pad and an anode connected to a ground point.
